(19) United States
(12) Patent Application Publication
(10) Pub. No.: US 2026/0223498 A1
(43) Pub. Date: Jul. 30, 2026

(54) PROCESS FOR MANUFACTURING AN EMISSIVE SYSTEM

(71) Applicant: Commissariat à l'Énergie Atomique et aux Énergies Alternatives, Paris (FR)

(72) Inventors: Quentin Abadie, Grenoble (FR); Nicolas Michit, Grenoble (FR); Carole Pernel, Grenoble (FR); Julia Simon, Grenoble (FR); Margaux Audibert, Grenoble (FR); Valentin Vivares, Grenoble (FR)

(73) Assignee: Commissariat à l'Énergie Atomique et aux Énergies Alternatives, Paris (FR)

(21) Appl. No.: 19/456,597

(22) Filed: Jan. 22, 2026

(30) Foreign Application Priority Data
Jan. 24, 2025 (FR) FR2500738

(51) Int. Cl. H10H 20/855; H10H 20/01; H10H 20/824; H10H 20/851

(52) U.S. Cl. CPC H10H 20/855; H10H 20/0363; H10H 20/824; H10H 20/8512

(57) ABSTRACT

An emissive system including an emissive portion, emitting at a first wavelength, and a lens covering the emissive portion, the lens and the emissive portion being made of a same III-V material, preferably selected from GaN, AlGaN, InGaN and InP, the lens having a core-shell structure with a porous shell, whereby the optical index of the shell is different from the optical index of the core of the lens. The emissive system is obtained according to the following steps: a) providing a structure including an emissive portion emitting at a first wavelength and a lens covering the emissive portion, b) electrochemically porosifying the shell of the lens.

### TECHNICAL FIELD

The present description generally relates to emissive systems and, more specifically, to emissive system devices comprising (micro)-lenses.

### BACKGROUND ART

The light-emitting diodes (LEDs) and the micro-LEDs (also known as μLEDs) based on InGaN/GaN have been extensively studied for the emission in the visible spectrum. They have reached an excellent degree of maturity thanks to their use in the field of lighting. The robustness and the high efficiency of LEDs based on GaN make them a preferred solution for making high-luminance and high-resolution micro-display screens.

In addition to optimizing the semiconductor stack and the electro-optical performance in the broad sense (Internal Quantum Efficiency (IQE)), it is critical to better manage the photons emitted by the LEDs.

The objective is not only to minimize the absorption losses and the optical noise (cross-talk) but also to extract as much light as possible from the LED at the correct wavelength.

For example, as described in the patent application EP 4 521 891 A1, it is possible to control the wavelength emitted by an LED by using porous mesas. By varying the porosity rate of the mesas, it is possible to modify the amount of indium incorporated into the surface of the mesas during the epitaxy of the LEDs and thus to control the emission wavelengths of the epitaxied LEDs.

The use of porous GaN in the manufacture of different LED structures is also presented, for example, in the review by Yao et al. (“The development and applications of nanoporous gallium nitride in optoelectronics: a review” (2023) Semicond. Sci. Technol. 38 074001).

However, for certain applications (augmented reality (AR)/virtual reality (VR), telecommunications for example), the directivity of the light beam emitted by the LED is also an important criterion.

To improve the extraction and the directivity, it is possible to optimize the design of the LED (cavity, thicknesses of the semiconductor stack), but also to add (micro)-optical elements to the LED.

Among the (micro)-optical elements that can be integrated into LEDs, there are among others:
the micro-lenses to improve the extraction and possibly the directivity,
the surface texturations to improve the extraction (LEE for ‘Light Extraction Efficiency’), in particular by roughening and integrating photonic crystals (extraction and directivity but not very compatible with small pixel pitches).

Micro-lenses are generally made of a dielectric material. They can be produced by flowing in a melted state a photosensitive resin in which patterns have been formed by photolithography, which is then flowed in a melted state and transferred by etching into another material (organic or inorganic). To maximize their performance, they are made of a same material as the micro-LED, or failing that, of a high-index material to ensure an index continuity (as described in the patent application FR 3 157 672 A1).

Among the possible strategies, we can also mention the one described in the patent application US 2023/0282680 A1, which provides a device comprising a stack of porosified GaN layers to extract light from the micro-LEDs and to improve the pixel isolation. However, the formed stack increases the size of the device, which makes it incompatible with all the applications.

### SUMMARY OF THE INVENTION

There is a need for an emissive system with improved optical properties, particularly with regard to extraction and directivity.

This objective is achieved by an emissive system comprising an emissive portion, emitting at a first wavelength, and a lens covering the emissive portion, the lens and the emissive portion being made of a same III-V material, preferably selected from GaN, AlGaN, InGaN and InP, the lens having a core-shell structure with a porous shell, whereby the optical index of the shell is different from the optical index of the core of the lens.

According to one particular embodiment, the first wavelength is between 440 and 460 nm.

According to one particular embodiment, the core of the lens is porous, the porosity rate of the core being greater than the porosity rate of the shell, spectral conversion elements being inserted into the core of the lens, the spectral conversion elements absorbing at the first wavelength and emitting at a second wavelength higher than the first wavelength.

According to one particular embodiment, the lens is hollow, the core of the lens being filled with spectral conversion elements absorbing at the first wavelength and emitting at a second wavelength higher than the first wavelength.

According to one particular embodiment, the second wavelength is between 520 and 700 nm.

According to one particular embodiment, the spectral conversion elements are quantum dots.

According to one particular embodiment, the porous shell has a porosity rate gradient from an outer surface of the shell toward the core of the lens.

This objective is also achieved by a process for manufacturing an emissive system as above defined, comprising the following steps:
a) providing a structure comprising an emissive portion, emitting at a first wavelength, and a lens covering the emissive portion, the lens and the emissive portion being made of a same III-V material, preferably selected from GaN, AlGaN, InGaN and InP,
b) electrochemically porosifying at least the shell of the lens, whereby the lens has a core-shell structure with a porous shell, the optical index of the shell being different from the optical index of the core of the lens.

According to one particular embodiment, the porosification step is performed by applying a single potential.

According to one particular embodiment, the porosification step is performed by applying a first potential and then a second potential, the first potential being different from the second potential.

### BRIEF DESCRIPTION OF THE DRAWINGS

The foregoing features and advantages, as well as others, will be described in detail in the following description of particular embodiments given on a non-limiting basis with reference to the accompanying drawings, in which:

FIG. 1, FIG. 2 and FIG. 3 illustrate, schematically and in cross-section, a part of an emissive system, according to different particular embodiments of the invention;

FIG. 4A, FIG. 4B, FIG. 4C, FIG. 4D, FIG. 4E, FIG. 4F and FIG. 4G are cross-sectional views illustrating steps of a process for manufacturing an optoelectronic structure to be porosified according to one particular embodiment of the invention;

FIG. 5A, FIG. 5B, FIG. 5C, FIG. 5D and FIG. 5E are cross-sectional views illustrating steps of a process for manufacturing an optoelectronic structure to be porosified according to another particular embodiment of the invention;

FIG. 6A, FIG. 6B, FIG. 6C, FIG. 6D, FIG. 6E, FIG. 6F and FIG. 6G are cross-sectional views illustrating steps of an example of an embodiment of a process for manufacturing an optoelectronic structure to be porosified according to another particular embodiment of the invention;

FIG. 7A is a graph illustrating the absorption of a resin comprising quantum dots (QD) as a function of the well/mirror distance and of the resin thickness reduced to the equivalent of the lens diameter (comparative example);

FIG. 7B is a graph illustrating the absorption of a GaN lens having a porosified shell and a porosified core into which QDs are inserted as a function of the well/mirror distance and of the lens diameter according to another particular embodiment of the invention;

FIG. 8A is a graph illustrating the extraction of a resin comprising QDs as a function of the well/mirror distance and of the resin thickness reduced to the equivalent of the lens diameter (comparative example);

FIG. 8B is a graph illustrating the extraction of a GaN lens having a porosified shell and a porosified core into which QDs are inserted as a function of the well/mirror distance and of the lens diameter according to another particular embodiment of the invention;

FIG. 9A is a graph illustrating the total extraction for a straight-sided LED covered by non-porosified lenses as a function of the lateral extent of the pixel and of the period of the array of lenses attached at 530 nm (comparative example); and

FIG. 9B is a graph illustrating the total extraction for a straight-sided LED covered by lenses having a porosified shell (with an optical index gradient from 2.4 to 1.7 from the outside of the shell to the core of the lens) and a non-porosified core as a function of the lateral extent of the pixel and of the period of the array of lenses attached at 530 nm according to another particular embodiment of the invention.

The various elements are not necessarily drawn to a uniform scale in order to make the figures more readable.

### DESCRIPTION OF THE EMBODIMENTS

The same elements have been designated by the same references in the various figures. In particular, the structural and/or functional elements common to the various embodiments may have the same references and may have identical structural, dimensional and material properties.

For the sake of clarity, only the steps and the elements useful for understanding the described embodiments have been illustrated and are detailed.

Unless otherwise specified, when reference is made to two elements connected to each other, this means directly connected without any intermediate elements other than conductors, and when reference is made to two elements coupled to each other, this means that these two elements may be connected or coupled through one or more other elements.

In the following description, when reference is made to absolute position qualifiers, such as the terms “front”, “rear”, “top”, “bottom”, “left”, “right”, etc., or to relative position qualifiers such as “above”, “below”, “upper”, “lower”, etc., or to orientation qualifiers such as “horizontal”, “vertical”, etc., reference is made, unless otherwise specified, to the orientation of the figures.

By the expression “emissive system”, we mean a system that emits energy in the form of electromagnetic radiation (in particular visible light or even ultraviolet light) into its environment. The emissive system is, in particular, a light-emitting diode (LED).

Unless otherwise specified, the expressions “about”, “approximately”, “substantially” and “of the order of” mean within 10%, preferably within 5%.

The expression “between X and Y” means that the limits X and Y are included.

By the expression “emission wavelength”, for example, we refer to the wavelength at which the emission spectrum has an intensity peak. For illustrative purposes only, the light-emitting diodes may have an emission spectrum whose intensity peak is between 380 nm and 490 nm.

A light-emitting diode comprises a stack of different doped semiconductor portions, between which there is an active zone (formed by quantum wells) emitting a light radiation. The light-emitting diodes can be adapted, for example, to emit a blue light, i.e. a light whose emission spectrum has an intensity peak at a wavelength between approximately 440 nm and 460 nm. The light-emitting (micro) diodes and (micro) lenses are made from a same semiconductor compound, for example based on an III-V compound such as GaN. By the expression “made from,” we mean that the light-emitting diodes mainly comprise this semiconductor compound (corresponding to the doped semiconductor layers on either side of the active zone), even if other compounds are present in the light-emitting diode.

By the term “micro-lens” or “micro-LED” (also written as μLED or μlens), we mean that the micro-lenses or the μLEDs have a largest dimension of less than 10 μm. Subsequently, even if the description refers to a lens, it may be a micro-lens (or vice versa) and/or even if the description refers to an LED, it may be a micro-LED (or vice versa).

The lenses are hemispherical: they are shaped like a half-sphere. One of the faces of the hemisphere is flat and forms a flat disc: this is the so-called inner surface in contact with the emissive portion 120. One of the faces of the hemisphere is curved (or spherical) and corresponds to the so-called outer surface.

By the expression “core-shell lens”, we mean a lens comprising two distinct zones: a nucleus (the core) surrounded by an envelope (the shell). The shell follows the contour of the outer surface.

By the expression “porosification or porosity rate”, we mean the ratio of the volume of pores to the total volume of a material.

The spectral conversion elements are elements making possible to convert at least in part the excitation light into an emission light having a higher wavelength. By way of illustration, they can be adapted to absorb blue light, i.e. whose wavelength is between approximately 440 nm and 460 nm, and to emit green light, i.e. whose wavelength is between approximately 520 nm and 530 nm, or even red light, i.e. whose wavelength is between approximately 630 nm and 640 nm.

In the following description, the mesas, also known as elevations, are relief elements. The surface of the mesas can be circular, hexagonal, square or rectangular. The largest dimension of the surface of the mesas ranges from 500 nm to 500 μm. For example, the largest dimension of a circular surface is the diameter. The thickness of the mesas corresponds to the dimension of the mesa perpendicular to the underlying stack. The spacing between two consecutive mesas can range from a few micrometers to a few tens of micrometers. The spacing ranges preferably from 50 nm to 20 μm. For example, it is of 5 μm. Even more preferably, it is between 1 and 2 μm.

The invention is particularly interesting for manufacturing micro-screens. The color micro-screens comprise pixels formed of blue, green and red sub-pixels (RGB pixels). In the following description, these sub-pixels will be referred to more simply as pixels for the sake of brevity. The pixels form the emissive portion of the system. The pixels may have a surface area greater than, less than or equal to the inner surface area of the lens.

The emissive portion could also be a VCSEL (Vertical Cavity Surface Emitting Laser).

We will now describe the process for manufacturing the emitting system.

The process comprises the following successive steps:
a) providing a structure 100 comprising an emissive portion (for example an LED or μLED) 120, emitting at a first wavelength, and a lens 135 covering the emissive portion 120, the lens 135 being made of a same III-V material as the emissive portion 120, the III-V material being preferably selected from GaN, AlGaN, InGaN and InP,
b) electrochemically porosifying at least the shell 136 of the lens 135, so as to form a core-shell structure, whereby the optical index of the shell 136 is different from the optical index of the core 137 of the lens 135.

The porosification makes it possible to porosify the outer surface of the lens 135 (i.e. the surface in contact with the electrolytic solution) and to obtain a lens having a porosified shell 136.

The shell 136 may have a same porosification rate from the outside of the lens 135 to the core 137 of the lens or a porosification gradient from the outside of the lens 135 to the core 137 of the lens (i.e. the porosification gradient is radial). The gradient is, for example, decreasing from the outside of the lens 135 towards the core 136 of the lens. It could be increasing. The shell 137 thus has a radial porosity gradient and therefore a radial optical index gradient.

With such lenses, the optical index is modified orthogonally to the curved outer surface of the lens 135 (not only vertically with respect to the emission of the emissive portion 120 but also radially).

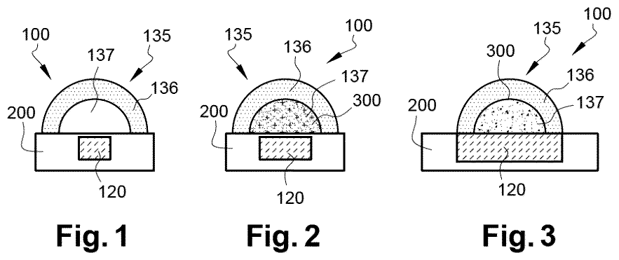

According to a first alternative embodiment, illustrated in FIG. 1, the porosification is performed in a single step. Only the shell 136 of the lenses is porosified. The core 137 of the lenses is not porosified.

This alternative embodiment makes it possible to provide additional degrees of freedom to improve the optical extraction of the assembly formed by the LED and the lens 135. In addition, for the same optical performance, the porosified lens 135 has dimensions that are easier to achieve than a non-porosified lens.

According to a second alternative embodiment, the porosification is a multipotential porosification. The porosification is performed in several sub-steps, for example in two steps (porosification known as double-potential porosification) or in more than two steps, each of the sub-steps being performed at a particular potential. The first potential makes it possible to porosify the shell 136 of the lens 135 and the second potential makes it possible to porosify the core 137 of the lens (FIG. 2).

The core 137 has a porosification rate higher than, lower than or equal to the porosification rate of the shell 136. Preferably, the porosification rate of the core 137 is higher than the porosification rate of the shell 136. The core 137 is highly porosified so that spectral conversion elements 300 (FIG. 2) can be incorporated into it.

When the potential is sufficiently high, we are placed in electropolishing conditions. The core 137 of the lens can be etched until all the III-V material is removed: a hollow lens (FIG. 3) is obtained. The core 137 can then be filled with spectral conversion elements 300 (FIG. 3).

By adding spectral conversion elements 300, for example quantum dots (QDs), in the core 137 of the lenses 135, the conversion function is transferred to the lenses 135.

The light emitted by the emissive portion 120 is converted within the lens 135. The lens 135 makes it possible not only to extract the photons from the emissive portion 120 but also to convert them.

The shell 136 has a porosity sufficient to allow the spectral conversion elements 300 to pass through to the core 137 of the lens 135. In other words, the smallest pore size is greater than the largest dimension of the spectral conversion elements 300.

We will now describe the steps a) and b) of the process in more detail.

The structure provided in the step a) can be obtained according to various particular embodiments.

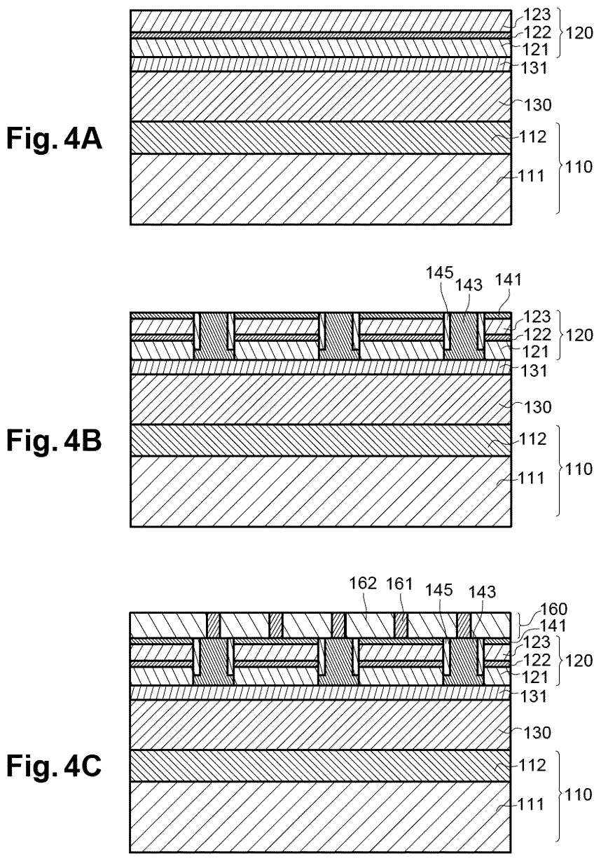

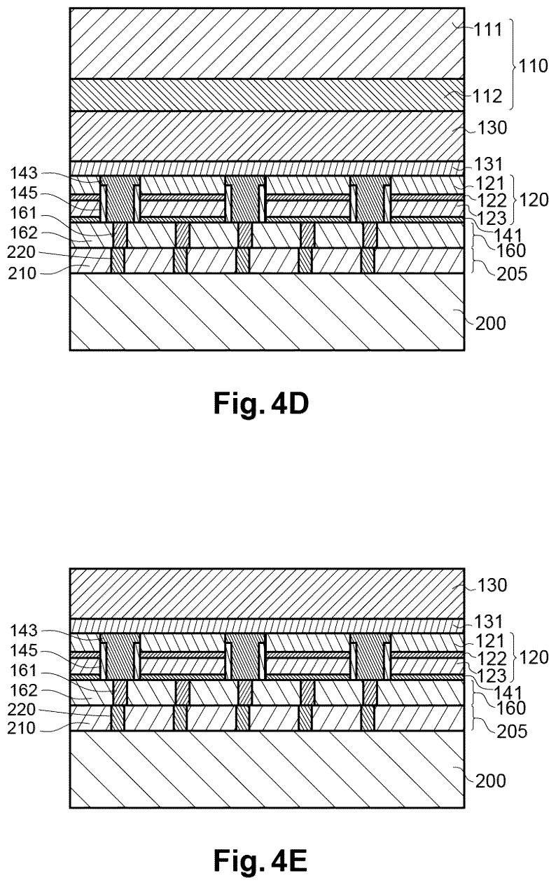

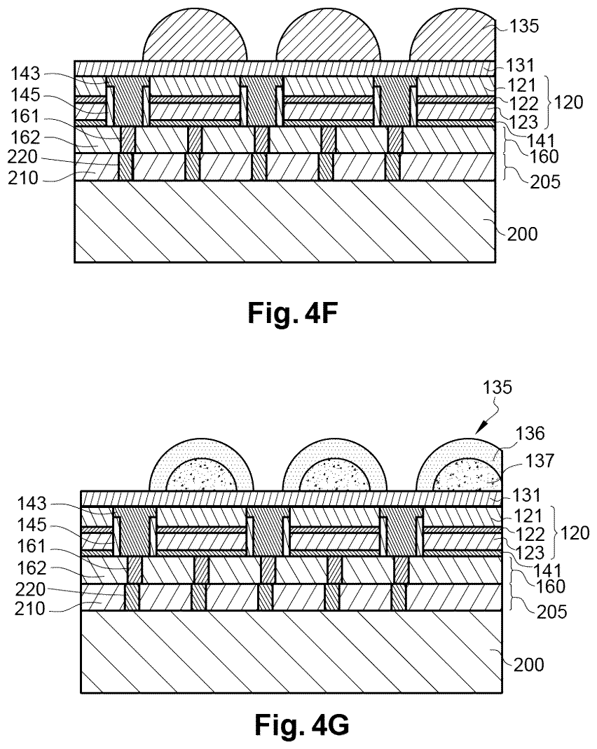

According to a first particular embodiment, for example illustrated in FIGS. 4A to 4E, the structure provided in the step a) can be obtained according to the following steps:
on a temporary substrate 110, covered by a n++GaN layer 130, and a nid GaN layer 131, growing by epitaxy an LED structure 120 (FIG. 4A);
depositing a first metallic layer 141, for example made of titanium, on the LED structure 120 and forming trenches through the stack 120 of epitaxied layers down to the n++GaN layer 130 or down to the nid GaN layer 131, then filling the trenches with a metal 143, for example titanium or titanium nitride, a passivation layer 145 being disposed between the metal 143 and the layers of the stack 120 (FIG. 4B),
forming a metallic/dielectric layer 160 comprising a dielectric material 162 in which conduction elements 161, for example made of copper, are formed, on the metallic layer 141 and on the metal 143 (FIG. 4C),
bonding the resulting assembly to the host substrate 200 (preferably of the ASIC type) covered by another metallic/dielectric layer 205 comprising a dielectric material 210 in which conductive elements 220 are formed, the bonding being a hybrid bonding (FIG. 4D),
removing the temporary substrate 110, for example by polishing (“grinding”), chemical etching or electrochemical process (FIG. 4E),
forming lenses 135 in the GaN++ layer 130 (“patterning”), for example by a photolithography process (resin deposition, flowing in a melting state, etching) (FIG. 4F).

The lenses are then porosified according to the above described process (FIG. 4G). The porosification step can be performed by making contact:
either on the host substrate 200 (i.e. via the read circuit of the host substrate 200),
or at the edge of the device (for example here at the edge of the plate) on the metallic layer 141 or on the N GaN layer 130 if it is not etched to its full thickness.

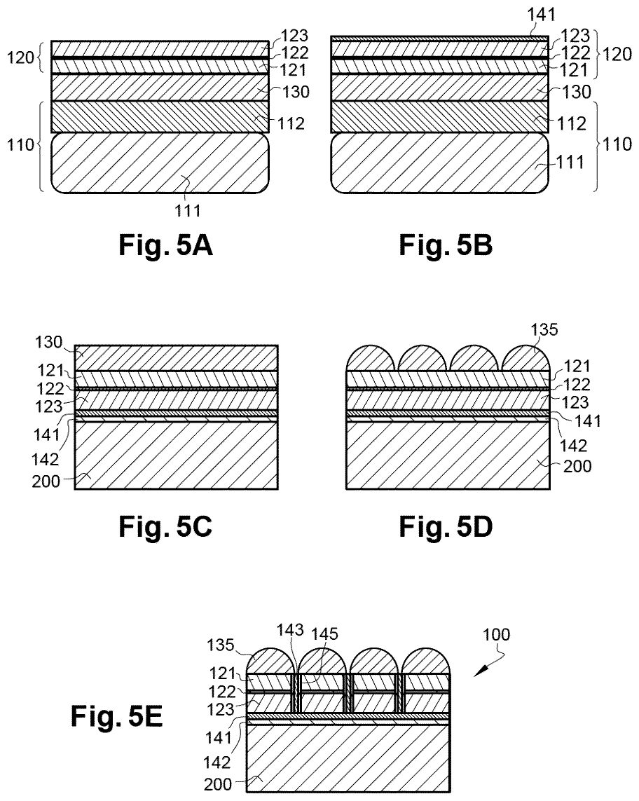

According to another alternative embodiment, for example illustrated in FIGS. 5A to 5E, a first metallic layer 141, for example made of titanium, is deposited on the LED structure 120 (FIG. 5B) and a second metallic layer 142, for example made of titanium, covers the host substrate 200. The bonding is a metal/metal bonding, preferably a Ti/Ti bonding (FIG. 5C).

According to an alternative embodiment, for example illustrated in FIG. 5E, the formation of the trenches and their filling 143 can be performed after the bonding of the host substrate 110 and of the temporary substrate 200 (before or after the formation of the lenses 135).

The electrochemical porosification step is performed via the read circuit of the host substrate 200 or via one of the metallic layers 141, 142 (FIG. 5E).

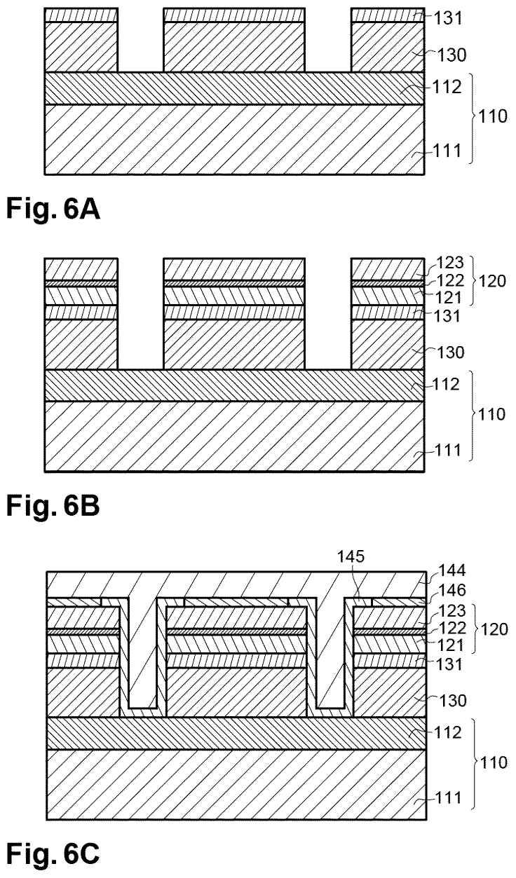

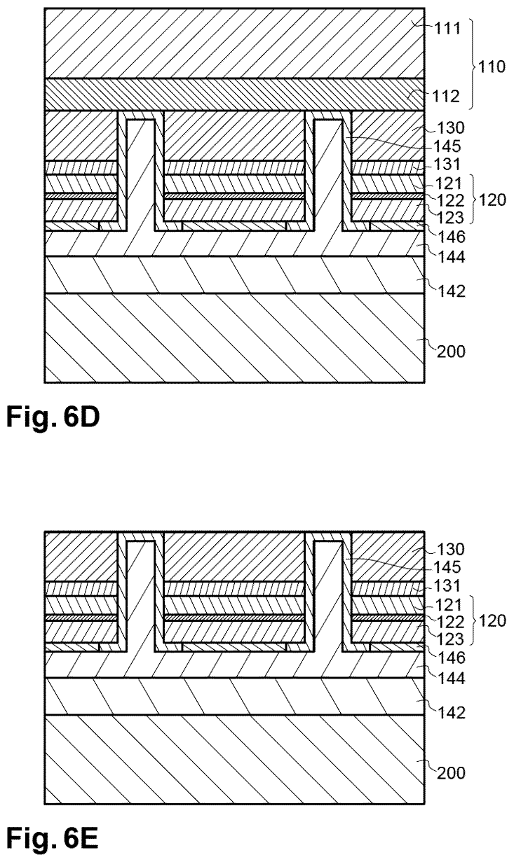

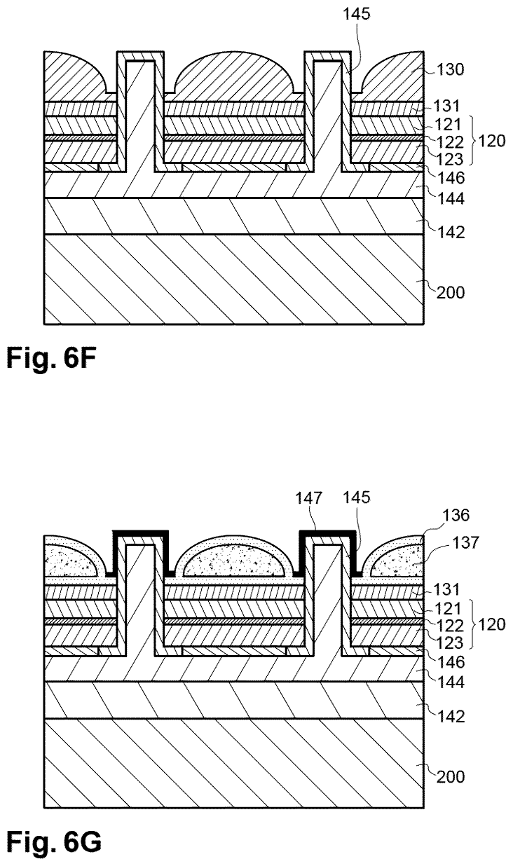

According to a second particular embodiment, for example illustrated in FIGS. 6A to 6G, the structure provided in the step a) can be obtained according to the following steps:
on a temporary substrate 110, depositing a n++ GaN layer 130 and a nid GaN layer 131, then structuring the n++ GaN layer 130 and the nid GaN layer 131 to form mesas (FIG. 6A),
growing by epitaxy an LED structure 120 on the mesas (FIG. 6B),
covering the sides of the mesas with an electrically insulating layer 145, depositing a metallic layer 146, acting as a primer layer, then depositing a metal 144 (for example titanium) between the mesas and on the mesas (FIG. 6C),
bonding the resulting assembly to a host substrate 200, which can be covered with a metallic layer 142, for example made of titanium, using a metal/metal bonding, preferably a Ti/Ti bonding (FIG. 6D),
removing the temporary substrate 100, for example by polishing (“grinding”), chemical etching, or electrochemical process (FIG. 6E),
forming lenses 135 in the GaN++ layer 130 (“patterning”), for example by a photolithography process (resin deposition, flowing in a melted state, etching) (FIG. 6F).

The electrochemical porosification step is performed via the read circuit of the host substrate 200 or via one of the metallic layers 142, 144, 146 or the n-GaN layer 130 (FIG. 6G).

This makes it possible to adapt the micro-lens to the wavelength of the micro-LED. Adjusting the porosity of the micro-lens according to the wavelength emitted by the pixel makes it possible to optimize the extraction by tuning the cavity.

In the above described various particular embodiments (FIG. 4A, 5A or 6A), the temporary substrate 110 (or growth substrate) comprises a support substrate 111 and, optionally, a buffer layer 112. In practice, depending on the nature of the substrate 110, a stack of several buffer layers may form an interface between the support substrate 111 and the gallium nitride layer 130. A buffer layer 112 may, for example, be made of (Al, Ga)N in the case of a silicon substrate. The support substrate 111 is, for example, a silicon, sapphire, or corundum substrate.

A doped GaN layer (n++ GaN layer) 130 in which the lenses 135 will be formed is formed on the substrate 100.

According to the first embodiment, the stack 120 is formed as a full plate on the GaN layer 130 or on a nid GaN layer 131 covering the GaN layer (FIGS. 4A, 5A).

According to the second embodiment, the n++GaN layer 130 is covered by a nid GaN layer 131, then these layers are structured in the form of mesas (FIG. 6A) before forming the stack 120 (FIG. 6B). The process then comprises a step during which trenches are formed in the n++ GaN layer 130 and in the GaN layer 131. The mesas are obtained, for example, by etching a continuous layer or several superimposed continuous layers, so as to leave only a certain number of “reliefs” of this layer or of these layers. The structuring step is, for example, performed by lithography followed by etching.

The LED forms an active stack 120. This is the emissive portion. The LED is, for example, deposited by epitaxy on the upper surface of the n++ GaN layer 130 (FIG. 5A) or on the nid GaN layer 131 (FIGS. 4A, 6B).

In the illustrated examples, the active stack 120 comprises, in order from the upper surface of the n++ GaN layer 130 or of the nid GaN layer 131, an N-type doped gallium nitride layer 121, an emissive layer 122 and a P-type doped gallium nitride layer 123. The emissive layer 122 is, for example, constituted by a stack of one or more emissive layers each forming a quantum well, for example based on GaN, InN, InGaN, AlGaN, AlN, AlInGaN, GaP, AlGaP, AlInGaP, or of a combination of one or more of these materials. As a variant, the emissive layer 122 may be an intrinsic gallium nitride layer, i.e. unintentionally doped, for example with a residual donor concentration between 10¹⁵ and 10¹⁸ atoms/cm³, for example of the order of 10¹⁷ atoms/cm³. In this example, the lower surface of the emissive layer 122 is in contact with the upper surface of the layer 121, and the upper surface of the emissive layer 122 is in contact with the lower surface of the layer 123. As an example, the thickness of the active stack 120 is between 0.5 and 2 μm.

The n++ GaN layer 130 is made of a same material as the emissive portion 120 to ensure an optical index continuity.

FIG. 5B or 6C illustrates a step of depositing a metallic layer 141 on the upper surface of the gallium nitride diode active stack 120. In the example illustrated in FIG. 5B, the metallic layer 141 is disposed on and in contact with the upper surface of the gallium nitride layer 123. The metallic layer 141 covers for example substantially the entire upper surface of the active stack.

In the case where the structure comprises mesas, a metal 144, for example copper, is deposited between the mesas (FIG. 6C). A primer layer 146 is preferably deposited prior to the deposition of the metallic layer 144 to facilitate the deposition of the latter. The primer layer 146 may be deposited as a full plate (FIG. 6C).

To avoid P-N short-circuiting, a passivation layer 145 is formed along the sides of the PN junction in the trench before the primer layer 146 or the metallic layer 144 is deposited.

FIG. 4D, FIG. 5C and FIG. 6D illustrate a step during which the LED active stack 120 is transferred on a host substrate 200.

The host substrate (or receiver substrate) 200 is, for example, a substrate made of a semiconductor material, particularly silicon, in which an integrated control circuit is formed. In particular, the control circuit comprises, on the side of its upper surface, for each of the LEDs of the device, a metallic connection pad to be connected to one of the electrodes (anode or cathode) of the LED, so as to be able to control a current flowing in the LED and/or to apply a voltage across the terminals of the LED. The control circuit comprises, for example, for each LED, connected to the metallic pad dedicated to the LED, an elementary control cell comprising one or more transistors, allowing the current flowing in the LED and/or a voltage applied across the terminals of the LED to be controlled. The control circuit is, for example, implemented by using CMOS technology. The metallic pads may be laterally surrounded by an insulating material, for example silicon oxide, so that the control circuit has a substantially flat upper surface comprising alternating metallic regions and insulating regions. The contact with the electrodes of the LEDs (cathodes or anodes) not connected to the pads can be made collectively, for example in a peripheral region of the control circuit, via one or more connection pads (not visible in the figure) of the control circuit.

A metallic layer 142 may be deposited on the upper surface of the host substrate 200 (FIG. 5C). In the illustrated example, the metallic layer 142 covers substantially the entire upper surface of the host substrate 200. In particular, the metallic layer 142 is in contact with the metallic connection pads 220 of the control circuit. It may also be a dielectric/metallic layer 205 (FIG. 4D).

Alternatively, the host substrate 200 may not be covered by a metallic layer and the bonding is performed directly on the upper surface of the substrate 200.

To perform the transfer step, the assembly comprising the temporary substrate 110 and the active stack 120 can be turned over and then transferred on the host substrate 200 so as to bring into contact, for example:
the metallic/dielectric layer 160 in contact with the metallic/dielectric layer 205 (FIG. 4D),
the metallic layer 141/144 and the metallic layer 142 covering the host substrate 200 (FIG. 5C or 6D).

During this step, the active stack 120 is bonded to the control circuit. For example, the active stack 120 can be fixed (“bonded”) to the control circuit by molecular bonding, preferably by hybrid bonding, between the two surfaces brought into contact. As a variant, the two surfaces can be bonded by thermo-compression or eutectic bonding.

The support substrate 110 of the LED active stack 120 is removed so as to expose the upper surface of the gallium nitride layer 123 (FIGS. 4C, 5D, 6E). The support substrate 110 is, for example, removed by grinding and/or etching from its surface opposite the active stack 120. As a variant, in the case of a transparent support substrate 110, for example a monocrystalline Al₂O₃ substrate, for example sapphire or corundum, the support substrate 110 can be detached from the active stack 120 by means of a laser beam projected through the substrate 151 from its surface opposite the active stack 120 (process of the laser lift-off type). More generally, any other method for removing the support substrate 110 may be used. After the removal of the substrate, an additional etching step may be provided to remove any remaining buffer layers on the side of the upper surface of the gallium nitride layer 130. In addition, a part of the thickness of the gallium nitride layer 130 may be removed, for example by etching.

A passivation layer 145 may then be formed on the metallic layer 144 between the mesas (FIG. 6C).

A lens formation step is then performed in the GaN layer 130 (FIGS. 4F, 5D and 6F). The step may be performed by photolithography. For example, the micro-lenses are made by flowing in a melted state a photosensitive resin in which patterns have been made by photolithography, which is then flowed in a melted state and transferred by etching.

The GaN layer is structured to form hemispherical lenses. The flat surface area of the lenses may be less than, equal to or greater than the surface area of the lenses. For example, the flat surface area of the lens may be twice as large as the surface area of the pixel.

In the resulting emissive system (FIGS. 4F, 5E and 6G) to be porosified, each LED corresponds to an island or mesa formed in the stack and laterally surrounded by a trench. The trenches extend vertically over the entire height of the stack 120. Thus, each LED comprises a vertical stack comprising, in order from the upper surface of the metallic layer 141/146: a portion of the gallium nitride layer 123, corresponding to the anode of the LED in these examples, a portion of the emissive layer 122 and a portion of the gallium nitride layer 121, corresponding to the cathode of the LED in these examples. The trenches may be arranged so that each LED is located, in vertical projection, opposite a single metallic pad of the control circuit (not illustrated here). The metallic layer 141/146 can serve as a contact recovery during the porosification.

After the step a), the step b) of porosification of the lenses 135 can then be carried out.

As previously indicated, the porosification step may be carried out in one step or in several sub-steps to form at least partially porous refractive lenses 135.

During the step b), the lenses 135 are partially or totally porosified.

The porosification can be performed according to the following sub-steps:
electrically coupling the structure and a counter-electrode to a voltage or current generator,
immersing the structure and the counter-electrode in an electrolytic solution,
applying at least one voltage or current between the lenses 135 and the counter-electrode so as to porosify the shell of the lenses.

The structure and the counter-electrode (CE) are electrically coupled to a voltage or current generator. The device acts as a working electrode (WE). Hereinafter, it will be referred to as a voltage generator but it could be a current generator used to apply a current between the device and the counter-electrode.

As above mentioned, the contact is made on the structure, on one of the edges of the structure, at the metallic layers 141, 142, 144 or at the GaN layer 130, or via the host substrate 200.

The counter-electrode is made of an electrically conductive material, such as for example a metal with a large developed surface area that is inert to the chemistry of the electrolyte, such as a platinum mesh.

The electrodes are immersed in an electrolyte, also known as an electrolytic bath or electrolytic solution. The electrolyte may be acidic or basic. The electrolyte is, for example, based on oxalic acid. It may also be KOH, HF, HNO₃, NaNO₃ or H₂SO₄. It may be a mixture of oxalic acid and of NaNO₃.

The voltage applied between the structure 100 and the counter-electrode can range, for example, from 1 to 100 V, preferably from 1 to 30 V, for example. Preferably, it ranges from 5 to 15 V and even more preferably, from 6 to 12 V, for example from 8 to 10 V. The voltage is selected according to the doping rates of the different layers in order to obtain the desired selectivity. It is applied, for example, for a duration ranging from a few seconds to several hours. The porosification is complete when there is no longer any current at an imposed potential. At this point, the entire doped structure is porosified and the electrochemical reaction stops.

For example, the porosification step is performed by applying a voltage of 9 V (non-pulsed) in an oxalic acid solution.

The electrochemical anodization step can be performed under ultraviolet (UV) light.

The obtained porosification (porosity rate and pore size) depends on the doping of the lens 135 and of the process parameters (applied voltage, duration, nature and concentration of the electrolyte, chemical post-treatment or annealing). In fact, at a constant doping rate, different porosity rates, pore sizes and densities are obtained depending on the applied potential.

By applying a single potential for a sufficiently short duration, it is possible to porosify only the shell 136 of the lenses 135. The porosification begins evenly on the edges of the lens. The longer the duration is, the thicker the porosified part is. The porosification step is stopped before the lenses 135 are completely porosified.

The implementation of a multi-step porosification step, with different potentials, makes it possible to obtain structured lenses with several differently porosified parts.

The first potential is preferably lower than the second potential.

At a low potential, the porosity rate and the pore size are low. This is a nucleation regime, leading to the creation of channels. The channels are created from the outer surface of the lenses 135, i.e. from the surface in contact with the electrolytic solution.

At a higher potential, the porosification regime, or even the electropolishing regime, is reached: the porosification spreads to the most conductive zones (in other words, to the central part 137 of the lens 135 that has not yet been involved in the electrochemical reactions, which consume charges).

The porosity rate of the core 137 of the lens 135 may be higher than the porosity rate of the shell 136. It is thus possible to subsequently introduce color conversion elements such as QDs.

In the case of a porous lens without a conversion function, the porosity rate of the core 137 of the lens 135 may be lower than the porosity rate of the shell 136.

At the end of the porosification step b), the porosity rate of the shell 136 is, advantageously, of at least 10%. It preferably ranges from 25% to 70%, preferably from 25% to 50%, for example from 45% to 50%.

The largest dimension (height) of the pores may vary from a few nanometers to a few micrometers (for example up to the maximum height of the lens). The smallest dimension (diameter) may vary from a few nanometers to a hundred nanometers, in particular between 15 and 70 nm.

When the core 137 of the lens 135 is empty or porous, the process may comprise a further step during which the core 137 of the lens 135 is partially or completely filled with spectral conversion elements 300. This step may be performed by filling the system with a fluid (preferably liquid) containing the light-converting elements.

The spectral conversion elements 300 may be fluorophores or quantum dots (QDs).

The QDs may be selected, for example, from CdSe/ZnS, ZnCdSe, CdZnS, InP, InP/ZnSe/ZnS and InP/ZnS.

The spectral conversion elements 300 absorb at a first wavelength (the one emitted by the emissive portion 120) and emit at a second wavelength. The second wavelength is higher than the first wavelength.

For example, the first wavelength is in the blue and the second wavelength is in the red.

Specific embodiments have been described. Various variants and modifications will be apparent to those skilled in the art. In particular, the conductivity types of the gallium nitride layers 121 (of the N-type in the described examples) and 124 (of the P-type in the described examples) can be reversed.

More generally, the described embodiments can be adapted to the manufacture of any display device or photosensitive sensor based on semiconductor diodes, including those based on semiconductor materials other than gallium nitride, for example diodes based on other III-V semiconductor materials or diodes based on silicon.

### Illustrative and Non-Limiting Examples

### 1^{st} Example

In this first example, we will use a 2D simulation to compare the characteristics of a lens with a porous shell and a porous core filled with quantum dots (index matrix n=1.7+0.008i) with the characteristics of a uniform layer of QDs positioned above the LED.

To normalize the results, we converted the thickness of the uniform layer so that the same number of QDs are present as in the case with lens. The thickness of the uniform layer of QDs is therefore expressed as an equivalent of the lens diameter. This makes it easier to compare the absorptions by QDs in both cases.

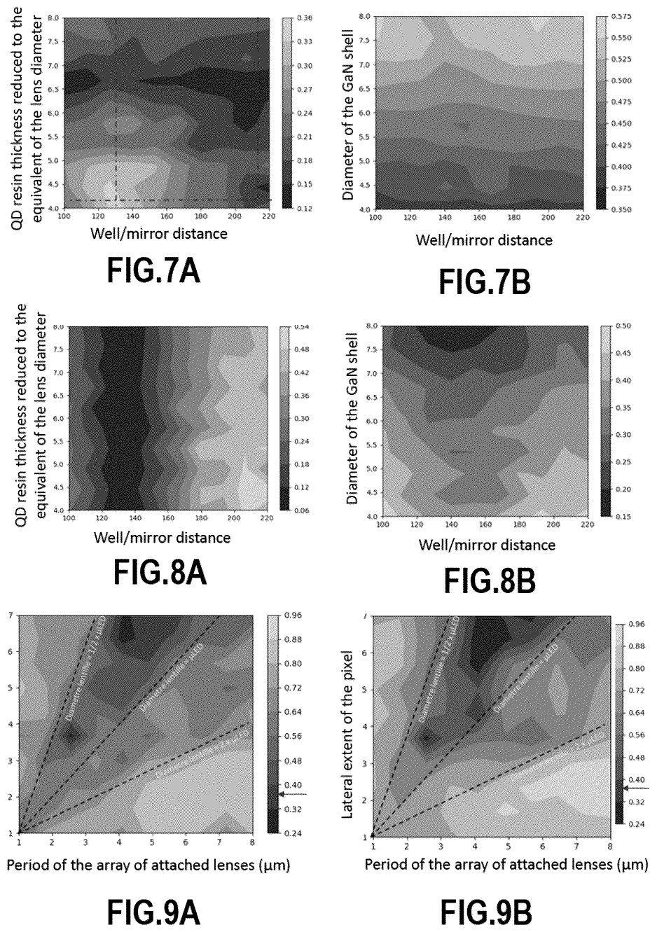

In the case without lens, the cavity is dominated by a Fabry-Pérot effect of the horizontal stack: thus, the absorption in the QDs depends on the distance between the quantum well and the reflective metal and on the height of the conversion layer. In the best configuration, an absorption of 30% is reached for a well/mirror distance of 130 nm (FIG. 7A).

When the lens is added above the LED, the Fabry-Pérot interferences are attenuated and the absorption in the QDs depends only on the diameter of the lens, which can be maximized. With a diameter of 8 μm, the absorption of the QDs reaches 60%, which is much higher than the result without lens (FIG. 7B).

The absorption of the QDs is important because of it depends the amount of converted light that is re-emitted. The simulation on the QDs re-emission is time-consuming because the source is distributed throughout the conversion layer but the results are fairly easy to intuit. The re-emission inside the lens is greatly facilitated by the extraction structure, whereas in a uniform layer, it is confined to the emission in the light cone of the air/QD matrix interface. In other words, both for the absorption part and the emission part, the solution with the lens offers an interesting performance.

Finally, in a conversion layer, it is important to emit light but it is also important not to let the excitation light pass through, as this would pollute the converted emission spectrum. We therefore look at the amount of blue light that passes through the QDs layer to create a crosstalk on the final system: this amount of light must therefore be minimized. In the case without lens, we regain the Fabry-Pérot effect with as main interference the one caused by the mirror/well distance. At a distance of 130 nm, the absorption was maximum in the QDs and the light transmission was minimum, around 10%. The addition of the lens reduces these effects and the blue light can be extracted more easily, which increases the crosstalk to a minimum of 15-20% in the case where the lens has a large diameter. This greater crosstalk can be counteracted with anti-reflective layers or more absorbent QDs, or even including scattering particles.

### 2^{nd} Example

In this second example, the core/shell structure of the lens comprises a non-porosified core and a porosified shell.

The simulation of the incoherent LED source was performed using Lumerical ANSYS in FDTD. The Figures in this section are maps of optical power (or of absorption) in the space (FIGS. 8A and 8B). The simulations of incoherent sources were performed in 2D, which allows to obtain the important information more quickly than with a 3D representation. The maps produced are slightly noisy but the obtained information remains nevertheless sufficiently clear. The expressed extraction or absorption values are given for illustrative purposes only and depend on the assumptions made about the materials and the simulated geometry.

For the optical simulations, we consider here a GaN lens integrated above a μLED. As such, the system's lens already improves the optical extraction compared to a μLED without lens. The lens is porosified to locally modify its optical index and thus increase its optical performance. The porosification is done in a manner compliant with the lens surface. By applying a voltage amplitude temporal gradient across the terminals of the electrodes, a porosification density gradient is created within the GaN lens, and thus an optical index gradient. Typically, a succession of time slots on the porosification voltage transfers a series of concentric shells of different indices into the lens.

This additional degree of freedom makes it possible to improve the optical performance of the device.

To illustrate this statement, we compare devices with and without porosification of the lens integrated above a pixel (FIGS. 8A and 8B). The value of interest is the optical extraction above the system and we seek to maximize it. The temporal shape of the applied voltage is a staircase that forms a series of eight shells with a thickness of 100 nm and an optical index of [2.4; 2.3; 2.2; 2.1; 2.0; 1.9; 1.8; 1.7]. This form of progressive porosification is an example of what can be achieved. To optimize the performance, the thickness/index pairs of each layer would need to be modified using an optimization algorithm capable of processing this number of parameters.

FIGS. 9A and 9B illustrate the simulated optical extraction of a lens (or of an array of attached lenses) with a diameter between 1 and 8 μm integrated above a pixel with an extent between 1 and 7 μm.

The optical performance is better when using a porosification of the lens with a high maximum extraction (clear zone). It should be noted that the optical extraction of the pixel/lens pair depends on the ratio between the two characteristic lengths. Placing a large-sized lens above a small-sized pixel or placing an array of small-sized lenses above a large-sized pixel will be advantageously selected. The lenses used have, for example, a diameter larger than 1 μm and less than 6 μm. Such lenses can be easily manufactured industrially.

In this respect, the solution involving lens porosification makes it possible to maintain the optical performance of a non-porosified lens and to change its dimensions to make it easier to manufacture. Thus, the level of performance achieved for a small pixel (<2 μm) and a non-porosified lens with a diameter of 6 μm can be achieved by a porosified lens with a diameter of 4 μm for a small pixel, but also by a lens with a diameter of 1 μm for larger pixels.

Various embodiments and variants have been described. Those skilled in the art will understand that certain features of these various embodiments and variants could be combined, and other variants will be apparent to those skilled in the art.

Finally, the practical implementation of the described embodiments and variants is within the reach of those skilled in the art based on the functional indications given above.

1. An emissive system comprising an emissive portion, emitting at a first wavelength, and a lens covering the emissive portion the lens and the emissive portion being made of a same III-V material, preferably selected from GaN, AlGaN, InGaN and InP, the lens having a core-shell structure with a porous shell, whereby the optical index of the shell is different from the optical index of the core of the lens, the lens being a hemispherical lens.

2. The system according to claim 1, wherein the first wavelength is between 440 and 460 nm.

3. The system according to claim 1, wherein the core of the lens is porous, the porosity rate of the core being greater than the porosity rate of the shell, spectral conversion elements being inserted into the core of the lens, the spectral conversion elements absorbing at the first wavelength and emitting at a second wavelength higher than the first wavelength.

4. The system according to claim 1, wherein the lens is hollow, the core of the lens being filled with spectral conversion elements absorbing at the first wavelength and emitting at a second wavelength higher than the first wavelength.

5. The system according to claim 3, wherein the second wavelength is between 520 and 700 nm.

6. The system according to claim 3, wherein the spectral conversion elements are quantum dots.

7. The system according to claim 1, wherein the porous shell has a porosity rate gradient from an outer surface of the shell toward the core of the lens.

8. A process for manufacturing an emissive system according to claim 1, comprising the following steps:
a) providing a structure comprising an emissive portion, emitting at a first wavelength, and a lens covering the emissive portion, the lens and the emissive portion being made of a same III-V material, preferably selected from GaN, AlGaN, InGaN and InP, the lens being a hemispherical lens,
b) electrochemically porosifying at least the shell of the lens, whereby the lens has a core-shell structure with a porous shell, the optical index of the shell being different from the optical index of the core of the lens.

9. The process according to claim 8, wherein the porosification step is performed by applying a single potential.

10. The process according to claim 8, wherein the porosification step is performed by applying a first potential and then a second potential, the first potential being different from the second potential.
